(19) United States
(12) Patent Application Publication
(10) Pub. No.: US 2023/0091745 A1
(43) Pub. Date: Mar. 23, 2023

(54) Film Bulk Acoustic Resonator and Manufacturing Method therefor, and Film Bulk Acoustic Wave Filter

(71) Applicant: Wuhan MEMSonics Technologies Co.,Ltd., Wuhan (CN)

(72) Inventors: Bangtao CHEN, Singapore (SG); Zhipeng DING, Singapore (SG); Bowoon SOON, Singapore (SG); Liyan SIOW, Singapore (SG); Feng GAO, Wuhan (CN); Yang ZOU, Wuhan (CN); Chengliang SUN, Wuhan (CN)

(21) Appl. No.: 17/949,249

(22) Filed: Sep. 21, 2022

(30) Foreign Application Priority Data
Sep. 22, 2021 (CN) 202111104999.0

(51) Int. Cl. H03H 9/205; H03H 3/02; H03H 9/54

(52) U.S. Cl. CPC H03H 9/205; H03H 3/02; H03H 9/54

(57) ABSTRACT

The disclosure provides a film bulk acoustic resonator and a manufacturing method therefor, and a film bulk acoustic wave filter, and relates to the technical field of resonators. The film bulk acoustic resonator includes a substrate, where the substrate is provided with two opposite protective walls protruding out of a surface of the substrate, a cavity is formed between the two protective walls, and an insulating layer is further arranged on one side, away from the cavity, of each protective wall on the substrate; and the film bulk acoustic resonator further includes a transducer stacking structure, where the transducer stacking structure covers the insulating layer, the cavity and the protective walls, and two sides, along a stacking direction, of the transducer stacking structure are in communication with the cavity and the outside respectively. With the cavity formed through the protective walls, the cavity being in communication with the outside, and the cavity formed by releasing corrosive substances to the cavity area from the outside, accurate control over cavity release machining is achieved, a process is simpler, cost is controlled, and a process period is shortened; an area proportion of the protective walls is small, and a chemical mechanical polishing (CMP) requirement is low, so as to advantageously improve a yield; and a structure of the film bulk acoustic resonator is built on the insulating layer, so as to advantageously reduce parasitic capacitance and resistance and improve comprehensive device performance.

### CROSS-REFERENCE TO RELATED APPLICATION

The disclosure claims the priority to Chinese Patent Application No. 202111104999.0, filed in China on Sep. 22, 2021 and entitled “Film Bulk Acoustic Resonator and Manufacturing Method therefor, and Film Bulk Acoustic Wave Filter”, which is incorporated herein by reference in its entirety.

### TECHNICAL FIELD

The disclosure relates to the technical filed of resonators, and particularly relates to a film bulk acoustic resonator and a manufacturing method therefor, and a film bulk acoustic wave filter.

### BACKGROUND

In the prior art, most film bulk acoustic resonators are cavity type resonators. A cavity, as the key to formation of performance of the film bulk acoustic resonator, provides an air layer with zero acoustic impedance for the resonator, and accordingly, its machining and manufacturing method is quite complex and vital. In an existing method for machining the cavity, a sacrificial layer is prefilled in the cavity, and then etching liquid is released to corrode the sacrificial layer to form and complete the cavity. However, such a method has certain problems as follows: the thick sacrificial layer is generally formed by film coating, which is likely to form residual stress in the film coating process and affect next steps of polishing and releasing the sacrificial layer; and it is extremely complex to polish-remove the sacrificial layer of several microns from the surface of an entire silicon wafer (especially a large-size silicon wafer), the precision is difficult to control, and the yield of the device is directly influenced.

### SUMMARY

The objective of the embodiments of the disclosure is to provide a film bulk acoustic resonator and a manufacturing method therefor, and a film bulk acoustic wave filter, so as to achieve accurate control over a cavity, a short process period, and high comprehensive device performance.

One aspect of the embodiments of the disclosure provides a film bulk acoustic resonator, including: a substrate, where two opposite protective walls protruding out of a surface of the substrate are arranged on the substrate, a cavity is formed between the two protective walls, and an insulating layer is further arranged on one side, away from the cavity, of each protective well on the substrate; and

the film bulk acoustic resonator further includes a transducer stacking structure, where the transducer stacking structure covers the insulating layer, the cavity and the protective walls, and two sides, along a stacking direction, of the transducer stacking structure are in communication with the cavity and the outside respectively.

Optionally, a through release channel along the stacking direction is arranged on the transducer stacking structure, and the release channel is in communication with the cavity.

Optionally, the transducer stacking structure includes a seed layer, a bottom electrode layer, a piezoelectric film layer, a mass loading layer, a top electrode layer, and a passivation layer stacked in sequence, and the seed layer is close to the insulating layer.

Optionally, the bottom electrode layer partially covers the seed layer, the mass loading layer partially covers the piezoelectric film layer, and the top electrode layer fully covers the mass loading layer and partially covers the piezoelectric film layer.

Optionally, ends of the bottom electrode layer and the top electrode layer along a first direction are arranged obliquely, an inclination angle between the end of the bottom electrode layer and a horizontal plane and an inclination angle between the end of the top electrode layer and the horizontal plane are less than 30°, and the first direction is perpendicular to the stacking direction.

Optionally, an angle between an end of the top electrode layer and a horizontal plane is 90°.

Optionally, material of the bottom electrode layer and material of the top electrode layer both include any one of platinum, aluminum, tungsten or molybdenum.

Optionally, an inclination angle of each of the protective walls ranges from 75° to 90°.

Optionally, a cross-sectional shape of the release channel in a horizontal plane includes circular or elliptical or polygonal section.

Another aspect of the embodiments of the disclosure provides a manufacturing method for a film bulk acoustic resonator. The manufacturing method includes: etching, on a substrate, two protective walls protruding out of a surface of a surface of the substrate; forming, on the substrate, an insulating layer, wherein a surface of the insulating layer flushes with a surface of of each protective wall at a side far away from the substrate; forming a transducer stacking structure on the insulating layer, wherein the transducer stacking structure is in communication with an insulating layer area between the two protective walls; and corroding the insulating layer area between the two protective walls through the transducer stacking structure, so as to form a cavity after the insulating layer area between the two protective walls is corroded.

Optionally, the corroding the insulating layer area between the two protective walls through the transducer stacking structure, so as to form a cavity after the insulating layer area between the two protective walls is corroded includes: forming a release channel, which connects the outside and the insulating layer area between the two protective walls, on the transducer stacking structure; and releasing etching liquid or etching gas through the release channel so as to corrode the insulating layer area between the two protective walls to form the cavity.

Optionally, an inclination angle of each of the protective walls ranges from 75° to 90°.

Optionally, the transducer stacking structure includes a seed layer, a bottom electrode layer, a piezoelectric layer and a top electrode layer; and the piezoelectric layer has a plurality of layers deposited.

Optionally, a projection area of the bottom electrode layer on a horizontal plane covers projection areas of the protective walls on the horizontal plane.

Optionally, a projection area of the top electrode layer on a horizontal plane is less than a projection area of the bottom electrode layer on the horizontal plane.

Optionally, the film bulk acoustic resonator forms an active area, and the release channel is arranged around an outer side of the active area, with a gap provided.

Optionally, the gap is, greater than a quarter of a wavelength.

Optionally, a cross-sectional shape of the release channel in a horizontal plane is a circular section

Yet another aspect of the embodiments of the disclosure provides a film bulk acoustic wave filter, including: a positive electrode, a negative electrode and a plurality of the film bulk acoustic resonators above, where the positive electrode is connected to a bottom electrode layer or a top electrode layer of one of the film bulk acoustic resonators, and the negative electrode is connected to a top electrode layer or a bottom electrode layer of another one of the film bulk acoustic resonators.

Optionally, the film bulk acoustic resonators include a plurality of first film bulk acoustic resonators and a plurality of second film bulk acoustic resonators, the plurality of first film bulk acoustic resonators are connected in series, and the plurality of second film bulk acoustic resonators are connected to the plurality of first film bulk acoustic resonators in parallel respectively.

According to the film bulk acoustic resonator, the manufacturing method therefor, and the film bulk acoustic wave filter provided in the embodiments of the disclosure, the two protruding protective walls are formed on the substrate, the two protective walls are oppositely arranged, the cavity is formed between the two protective walls, the insulating layer is further arranged on one side, away from the cavity, of each protective wall on the substrate, the insulating layer is divided into two areas by the protective walls and the cavity, the insulating layer, the protective walls and the cavity are located at one level, an energy conversion stacking structure is further arranged on the layer where the insulating layer, the protective walls and the cavity are located, and the energy conversion stacking structure covers the insulating layer, the cavity and the protective walls, to form a structure with the substrate, the insulating layer and the transducer stacking structure stacked in sequence; and moreover, two sides, along the stacking direction, of the transducer stacking structure are in communication with the cavity and the outside respectively, such that the cavity is in communication with the outside. With the cavity formed through the protective walls, and the cavity being in communication with the outside, an entity in an original cavity area may be corroded to form the cavity through corrosive substances released to the cavity area from the outside, then accurate control over cavity release machining is achieved, a technological operation flow is simpler, cost is controlled, and a process period is shortened; in addition, the area of the protective walls is small in proportion of the entire film bulk acoustic resonator, such that the requirement for chemical mechanical polishing (CMP) is low when the protective walls are prepared, and the yield is advantageously improved; and moreover, the film bulk acoustic resonator structure provided in the embodiment of the disclosure is built on the insulating layer, such that the film bulk acoustic resonator may be machined on a silicon substrate and may also be monolithically integrated on a complementary metal-oxide-semiconductor transistor (CMOS), and further, the insulating layer may advantageously reduce parasitic capacitance and resistance and improving comprehensive device performance.

Further, the manufacturing method for a film bulk acoustic resonator includes: etching, on a substrate, two protective walls protruding out of a surface of the substrate; forming, on the substrate, an insulating layer, wherein a surface of the insulating layer flushes with a surface of each protective wall at a side far away from the substrate; forming a transducer stacking structure on the insulating layer, wherein the transducer stacking structure is in communication with an insulating layer area between the two protective walls; and corroding the insulating layer area between the two protective walls through the transducer stacking structure, so as to form a cavity after the insulating layer area between the two protective walls is corroded. Etching liquid or etching gas is released into the insulating layer area to corrode the insulating layer area, so as to obtain the cavity. The method for manufacturing the cavity is simple and low in cost.

### BRIEF DESCRIPTION OF THE DRAWINGS

To describe the technical solutions in the embodiments of the disclosure more clearly, the accompanying drawings required in the embodiments of the disclosure will be briefly described below. It is to be understood that the following accompanying drawings show merely some embodiments of the disclosure and are therefore not to be considered as limiting the scope, and those of ordinary skill in the art can still derive other related accompanying drawings from these accompanying drawings, without making creative efforts.

FIG. 1 is a schematic diagram of a partial structure of an existing film bulk acoustic resonator;

FIG. 2 is a structural schematic diagram of a film bulk acoustic resonator according to an embodiment;

FIG. 3 is a flowchart of a manufacturing method for a film bulk acoustic resonator according to an embodiment;

FIG. 4 is a first schematic diagram of a manufacturing process of a film bulk acoustic resonator provided in an embodiment;

FIG. 5 is a second schematic diagram of a manufacturing process of a film bulk acoustic resonator provided in an embodiment;

FIG. 6 is a third schematic diagram of a manufacturing process of a film bulk acoustic resonator provided in an embodiment;

FIG. 7 is a fourth schematic diagram of a manufacturing process of a film bulk acoustic resonator provided in an embodiment;

FIG. 8 is a schematic top view of a connection structure of a film bulk acoustic resonator provided in an embodiment and an external circuit; and

FIG. 9 is a schematic top view of a film bulk acoustic wave filter structure provided in an embodiment.

### REFERENCE NUMERALS

101—silicon substrate; 102—cavity; 103—silicon wafer surface; 110—piezoelectric layer; 100—film bulk acoustic resonator; 100A—first film bulk acoustic resonator; 100B—second film bulk acoustic resonator; 10—substrate; 11—insulating layer; 111—protective wall; 112—cavity; 112A—insulating layer area; 12—seed layer; 13—bottom electrode layer; 14—piezoelectric film layer; 15—mass loading layer; 16—top electrode layer; 17—passivation layer; 18—release channel; 21—positive electrode; 22—negative electrode; 23—ground electrode; F—stacking direction; and F1—first direction.

### DETAILED DESCRIPTION OF THE EMBODIMENTS

The technical solutions of embodiments of the disclosure will be described below clearly and comprehensively in conjunction with accompanying drawings of the embodiments of the disclosure.

In the description of the disclosure, it is to be noted that the orientation or positional relation indicated by terms “in”, “out”, etc. is based on the orientation or positional relation shown in the accompanying drawings, or the orientation or positional relation of a product conventionally placed during use, merely for ease of description and simplification of the description of the disclosure, and not to indicate or imply that the referenced device or element must have a particular orientation and be constructed and operative in a particular orientation, and thus may not be construed as a limitation on the disclosure. Moreover, the terms “first”, “second”, etc. are used merely to distinguish between descriptions and may not be understood as indication or implication of relative importance.

It is to be further noted that unless otherwise explicitly specified and defined, the terms “arranging” and “connection” should be understood in a broad sense, for example, they may be a fixed connection, a detachable connection, or an integrated connection, and may be a direct connection, or an indirect connection via an intermediate medium, or communication inside two elements. For those of ordinary skill in the art, the specific meanings of the above terms in the application could be understood according to specific circumstances.

In a cavity type resonator, a cavity 102 is the key to formation of performance of a film bulk acoustic resonator. When an existing cavity type resonator is manufactured, a machining and manufacturing method for the cavity 102 is extremely complex, as shown in FIG. 1, a piezoelectric layer 110 is formed on a silicon substrate 101, during formation of the cavity 102, a sacrificial layer (not shown in the figure) is prefilled in the cavity 102, and then etching liquid is released to corrode the sacrificial layer to form and complete the cavity 102. However, such a method mainly has the defects as follows: firstly, the thick sacrificial layer has the thickness of several microns, filling by film coating is likely to form residual stress in the film coating process and affect next steps of chemical mechanical polishing (CMP) and releasing of the sacrificial layer; it is extremely complex to polish-remove the sacrificial layer of several microns from the entire silicon wafer surface 103 (especially a large-size silicon wafer), the precision is difficult to control, and the yield of the device is directly influenced; and an acoustic wave device structure is built on the silicon substrate 101, such that monolithic integration on a complementary metal-oxide-semiconductor transistor (CMOS) is difficult to, achieve, and an application range is limited.

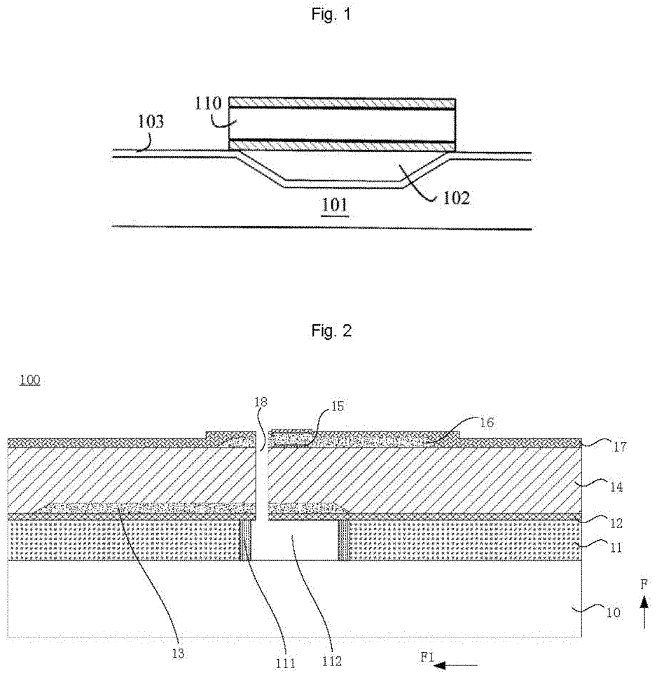

For solving the above problem, on this basis, the embodiments of the disclosure provide a film bulk acoustic resonator 100. With reference to FIG. 2, the film bulk acoustic resonator includes: a substrate 10, where two opposite protective walls 111 protruding out of a surface of the substrate 10 are arranged on the substrate 10, a cavity 112 is formed between the two protective walls 111, and an insulating layer 11 is further arranged on one side, away from the cavity 112, of each protective wall 111 on the substrate 10.

The film bulk acoustic resonator 100 further includes a transducer stacking structure, where the transducer stacking structure covers the insulating layer 11, the cavity 112 and the protective walls 111, and two sides, along a stacking direction F, of the transducer stacking structure are in communication with the cavity 112 and the outside respectively.

As can be seen from FIG. 2, the transducer stacking structure is integrally built on the insulating layer 11. Compared with a transducer stacking structure built on a silicon substrate in the prior art, the transducer stacking structure is built on the insulating layer 11, such that the film bulk acoustic wave filter formed by the film bulk acoustic resonator 100 may be machined on a silicon substrate and may also be monolithically integrated on a CMOS, and moreover, the insulating layer 11 and the substrate 10 serve as insulating dielectric substrates, so as to advantageously reduce parasitic capacitance and resistance and improve the comprehensive device performance.

The two protective walls 111 are oppositely arranged and protrude out of the surface of the substrate 10, a cavity 112 is formed between the two protective walls 111, the cavity 112 may limit longitudinally-propagated sound waves in the transducer stacking structure, the protective walls 111, the cavity 112 and the insulating layer 11 are located on one level along the stacking direction F, the insulating layer 11 is divided into two areas by the cavity 112 between the two protective walls 111 and the protective walls 111, and the transducer stacking structure is integrally formed on the protective walls 111, the cavity 112 and the insulating layer 11, that is, the transducer stacking structure covers the insulating layer 11, the cavity 112 and the protective walls 111.

The substrate 10, the insulating layer 11 and the transducer stacking structure are stacked in sequence, along the stacking direction F, one side of the transducer stacking structure is in communication with the cavity 112, the other side of the transducer stacking structure is in communication with the outside, that is, the cavity 112 is in communication with the outside.

The protective walls 111 are used for isolating the cavity 112 from the insulating layer 11, such that the protective walls 111 are used for ensuring that the insulating layer 11 is not excessively corroded and only positioning and releasing an entity portion in an original cavity area, that is, an insulating layer area 112A originally located in the cavity area. A size and a shape of the cavity 112 are controlled by arranging the protective walls 111, and after the cavity 112 is in communication with the outside, by releasing the corrosive substances to the cavity area, the entity (that is, the insulating layer area 112A) of the original cavity area is corroded to form the cavity 112, so as to accurately control the cavity 112, a process flow is simple, and cost is low. On the other hand, as can be seen in FIG. 2, the protective walls 111 has a small size, and the protective walls 111 are generally implemented in a polishing process, and an area proportion of the protective walls 111 is small in the entire film bulk acoustic resonator 100, such that when the protective walls 111 are polished, an area required to be polished is small, a CMP requirement is low, and the yield of the entire film bulk acoustic resonator 100 is advantageously improved.

According to the film bulk acoustic resonator 100 provided in the embodiments of the disclosure, the two protruding protective walls 111 are arranged on the substrate 10, the two protective walls 111 are oppositely arranged, the cavity 112 is formed between the two protective walls 111, the insulating layer 11 is further arranged on one side, away from the cavity 112, of each protective wall 111 on the substrate 10, the insulating layer 11 is divided into two areas by the protective walls 111 and the cavity 112, the insulating layer 11, the protective walls 111 and the cavity 112 are located at one level, an energy conversion stacking structure is further arranged on the layer where the insulating layer 11, the protective walls 111 and the cavity 112 are located, and the energy conversion stacking structure covers the insulating layer 11, the cavity 112 and the protective walls 111, to form a structure with the substrate 10, the insulating layer 11 and the transducer stacking structure stacked in sequence; and moreover, two sides, along the stacking direction, of the transducer stacking structure are in communication with the cavity 112 and the outside respectively, such that the cavity 112 is in communication with the outside. The cavity 112 is formed through the protective walls 111, the cavity 112 is in communication with the outside, and an entity in an original cavity area may be corroded to form the cavity 112 through corrosive substances released to the cavity area from the outside, such that accurate control over cavity 112 release machining is achieved, a technological operation flow is simpler, cost is controlled, and a process period is shortened. Moreover, the area of the protective walls 111 accounts for a small proportion of the entire film bulk acoustic resonator 100, such that the requirement for CMP is low when the protective walls 111 are manufactured, and the yield is advantageously improved. Moreover, the film bulk acoustic resonator 100 structure provided in the embodiment of the disclosure is built on the insulating layer 11, such that the film bulk acoustic resonator 100 may be machined on a silicon substrate and may also be monolithically integrated on a CMOS. Further, the insulating layer 11 may advantageously reduce parasitic capacitance and resistance and improve comprehensive device performance.

Further, a through release channel 18 along the stacking direction F is arranged on the transducer stacking structure, and the release channel 18 is in communication with the cavity 112.

The release channel 18 penetrates the two sides of the transducer stacking structure along the stacking direction F, the side, close to the insulating layer 11, of the release channel 18 of the transducer stacking structure is in communication with the cavity 112 after the release channel penetrates the transducer stacking structure, the cavity 112 is in communication with the outside through the release channel 18, therefore, the corrosive substances may be released into the cavity area through the release channel 18, and the cavity 112 is formed by releasing the entity of the original cavity area.

In general, the corrosive substance is etching liquid or etching gas, which is released through the release channel 18 to the cavity area, to corrode the cavity area, so as to obtain the cavity 112.

The release channel 18 is arranged for corroding, to form the cavity 112, such that corrosion releasing for the cavity 112 may be accurately controlled, and the cavity 112 with a size and shape satisfying requirements may be obtained by corroding the entity between the two protective walls 111. The operation is simpler, a period of the process flow is shortened, and the cost is saved.

It is to be noted that the protective walls 111 are made of a material which is non-corrodible by etching liquid or etching gas, and the etching liquid or etching gas refers to etching liquid or etching gas used in a manufacturing process of the cavity type bulk acoustic wave device.

The transducer stacking structure includes a seed layer 12, a bottom electrode layer 13, a piezoelectric film layer 14, a mass loading layer 15, a top, electrode layer 16, and a passivation layer 17 stacked in sequence, and the seed layer 12 is close to the insulating layer 11. The seed layer 12 covers an area excluding the release channel 18, the bottom electrode layer 13 only partially covers the seed layer 12, the area covered by the piezoelectric film layer 14 and the seed layer 12 is the same, the mass loading layer 15 only has a small area to partially cover the piezoelectric film layer 14, the top electrode layer 16 on the mass loading layer 15 is wrapped around the mass loading layer 15, completely covers the mass loading layer 15, and partially covers the piezoelectric film layer 14, and the passivation layer 17 is wrapped around and fully covers the top electrode layer 16 and partially covers the piezoelectric film layer 14. Moreover, the release channel 18 sequentially penetrates the passivation layer 17, the top electrode layer 16, the piezoelectric film layer 14, the bottom electrode layer 13 and the seed layer 12 to be in communication with the cavity 112, and the mass loading layer 15 is located on one side of the release channel 18.

The transducer stacking structure includes a seed layer 12, a bottom electrode layer 13, a piezoelectric layer 14 and a top electrode layer 15. Firstly, one seed layer 12 grows on the insulating layer, and the seed layer 12 is deposited through a metal organic chemical vapor deposition (MOCVD) method, with a temperature ranging from 600° C. to 1400° C., and a thickness ranging from 1 nm to 100 nm. The seed layer 12 is subjected to surface treatment to reduce its surface roughness. A bottom electrode layer 13 is deposited on the seed layer 12 and patterned. A piezoelectric layer 110 is deposited on the bottom electrode layer 13. The piezoelectric layer 110 may be deposited repeatedly, and a condition of each deposit is controlled, so as to control positive and negative stress of each layer of the piezoelectric layer 110. By alternately depositing the piezoelectric layer 110 with positive stress and negative stress, the internal stress of the entire piezoelectric layer 110 is balanced. The piezoelectric layer 110 may be obtained by physical vapor deposition (PVD), MOCVD, atomic layer deposition (ALD), etc. A top electrode layer 16 is deposited on the piezoelectric layer 110. Preferably, an edge of a projection of the bottom electrode layer 13 on a horizontal plane is located outside inner edges of the protective walls 111, and a projection of the top electrode layer 16 on the horizontal plane is smaller than a projection of the bottom electrode layer 13 on the horizontal plane.

The bottom electrode layer 13 and the top electrode layer 16 are arranged to connect electrodes, such that material of the bottom electrode layer 13 and material of the top electrode layer 16 both include any one of platinum, aluminum, tungsten or molybdenum. Moreover, along a first direction F1 perpendicular to the stacking direction F, that is, along a length direction in FIG. 2, ends of the bottom electrode layer 13 and the top electrode layer 16 are arranged obliquely. In a possible implementation mode of the disclosure, an inclination angle of the bottom electrode layer 13 and an inclination angle of the top electrode layer 16 both are less than 30°, and the inclination angles are the angles between the ends of the electrode layers and the horizontal plane.

Optionally, an angle between an end of the top electrode layer 16 and a horizontal plane is 90°. Through a vertical etching method, the top electrode layer 16 is vertically arranged, when an edge of the top electrode layer is 90°, sound waves at the edge may be well reflected, and a Q value of a resonator is improved.

An inclination angle of each of the protective walls 111 ranges from 75° to 90°. Deep reactive ion etching is used, and C4F8 gas and SF6 gas are alternately introduced into the reaction chamber. The C4F8 gas is introduced, such that a polymer film may be formed on a surface of a silicon side wall, and the purpose of passivation is achieved. The SF6 gas is introduced for physical and chemical etching. By alternately introducing the C4F8 and SF6 gas, passivation and etching are alternately performed, such that the inclination angle of the side walls of the protective walls 111 is controlled. The larger the inclination angle of the side walls of the protective walls 111 is, the better reflection of edge sound waves is, such that the 0 value of the resonator is improved, but stability of the protective walls 111 is reduced.

A cross-sectional shape of the release channel 18 in a horizontal plane includes circular or elliptical or polygonal section.

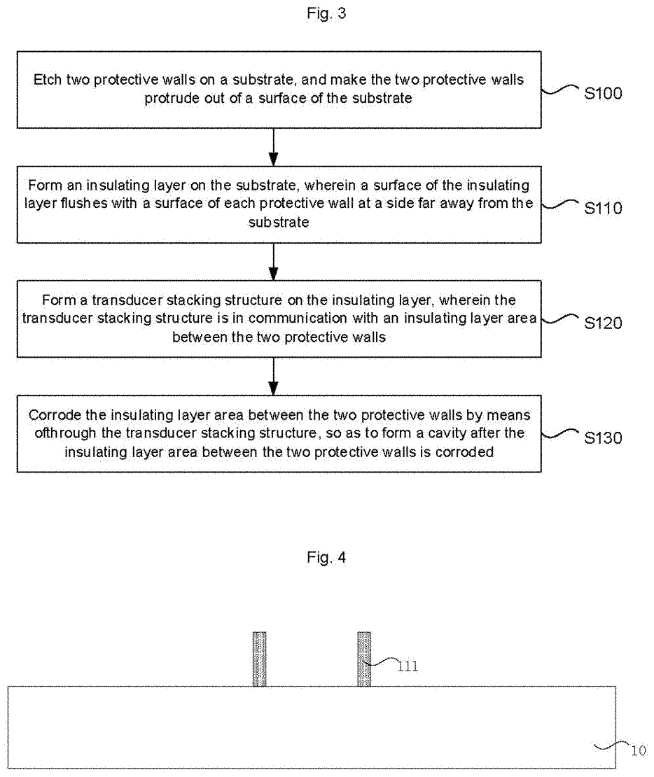

In another aspect, with reference to FIG. 3, the embodiments of the disclosure further provide a manufacturing method for a film bulk acoustic resonator 100. The method specifically includes:

S100: etch two protective walls 111 on a substrate 10, and make the two protective walls 111 protrude out of a surface of the substrate 10

As shown in FIG. 4, the protective walls 111 used for ensuring that an insulating layer 11 is not excessively corroded is etched on the substrate 10, and the protective walls 111 protrude out of a surface of the substrate 10.

S110: form an insulating layer 11 on the substrate 10, wherein a surface of the insulating layer 11 flushes with a surface of each protective wall 111 at a side far away from the substrate 10.

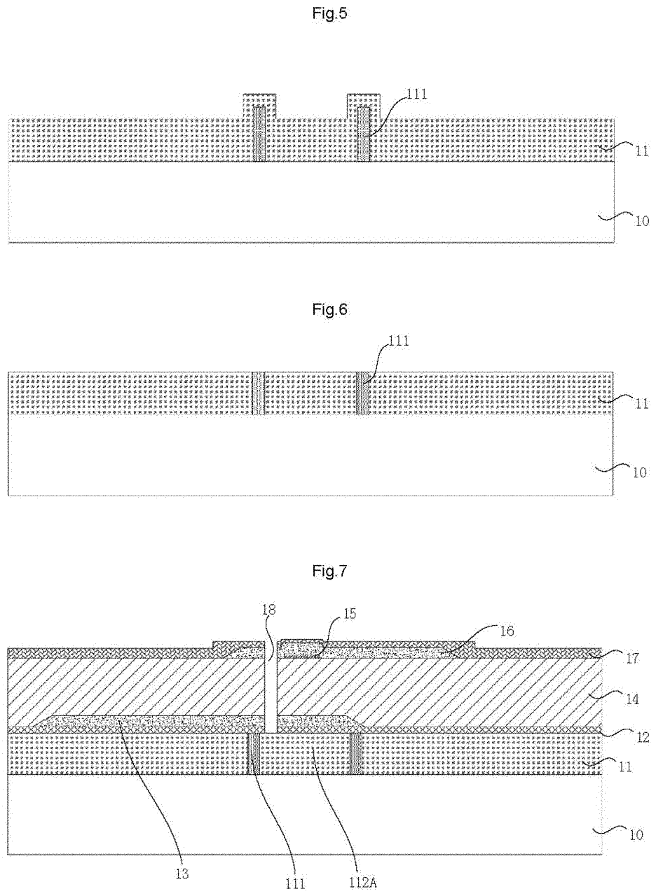

As shown in FIG. 5, one insulating layer 11 grows on the substrate 10. Then as shown in FIG. 6, the excess insulating material and protective walls 111 are removed, such that upper surfaces of the insulating layer 11 and the protective walls 111 are on one horizontal plane. The excess insulating material and protective walls 111 may be polished-removed to ensure surface smoothness.

S120: form a transducer stacking structure on the insulating layer 11, wherein the transducer stacking structure is in communication with an insulating layer area 112A between the two protective walls 111.

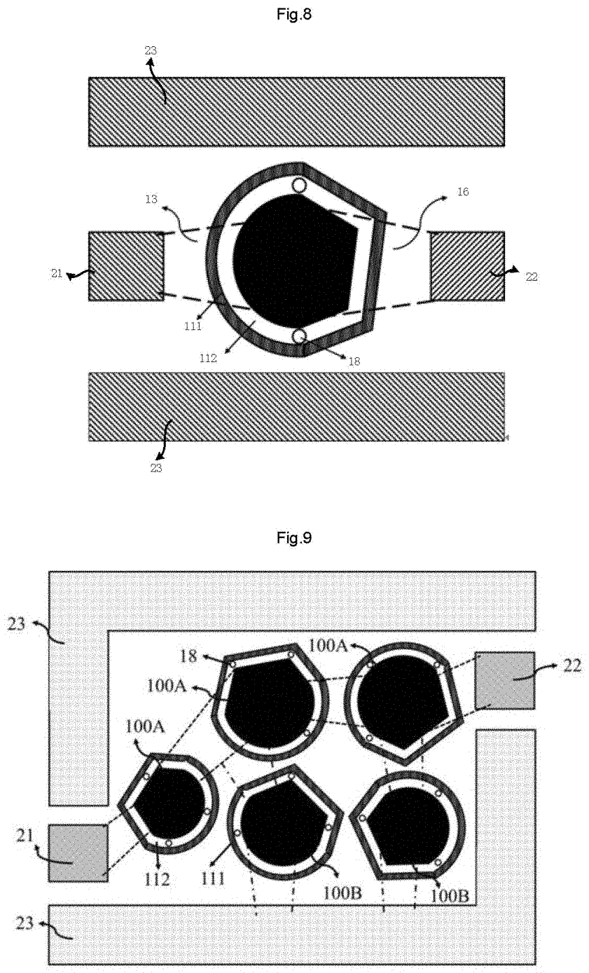

As shown in FIG. 7, a transducer stacking structure with a release channel 18 grows on the insulating layer 11 having the protective walls 111, and the transducer stacking structure covers a cavity area delimited by the protective walls 111 and the substrate 10. In this case, the cavity area is an insulating layer area 112A, the area is filled with an insulating layer 11 material, and the release channel 18 penetrates the transducer stacking structure and is located above the cavity area.

S130: corrode the insulating layer area 112A between the two protective walls 111 through the transducer stacking structure, so as to form a cavity 112 after the insulating layer area 112A between the two protective walls 111 is corroded

Specifically, the release channel 18 is formed on the transducer stacking structure, and the release channel 18 is in communication with the outside and the insulating layer area 112A between the two protective walls 111.

Etching liquid or etching gas is released through the release channel 18 so as to corrode the insulating layer area 112A between the two protective walls 111 to form the cavity 112 as shown in FIG. 2.

The protective walls 111 are made of a material which is non-corrodible by the etching liquid or the etching gas, such that when the etching liquid or the etching gas is released to the insulating layer area 112A through the release channel 18, the etching liquid or the etching gas only corrodes the insulating layer, area 112A and does not corrode the protective walls 111, so as to protect the insulating layer 11 on two sides of the protective walls 111.

Optionally, an inclination angle of each of the protective walls 111 ranges from 75° to 90°. Deep reactive ion etching is used, and C4F8 gas and SF6 gas are alternately introduced into the reaction chamber. The C4F8 gas is introduced, such that a polymer film may be formed on a surface of a silicon side wall, and the purpose of passivation is achieved. The SF6 gas is introduced for physical and chemical etching. By alternately introducing the C4F8 and SF6 gas, passivation and etching are alternately performed, such that the inclination angle of the side walls of the protective walls 111 is controlled. The larger the inclination angle of the side walls of the protective walls 111 is, the better reflection of edge sound waves is, such that the Q value of the resonator is improved, but stability of the protective walls 111 is reduced.

Optionally, the transducer stacking structure includes a seed layer 12, a bottom electrode layer 13, a piezoelectric layer 110 and a top electrode layer 16; and the piezoelectric layer 110 has a plurality of layers deposited. A condition of each deposit is controlled, so as to control positive and negative stress of each layer of the piezoelectric layer 110. By alternately depositing the piezoelectric layer 110 with positive stress and negative stress, the internal stress of the entire piezoelectric layer 110 is balanced. The piezoelectric layer 110 may be obtained by physical vapor deposition (PVD), MOCVD, atomic layer deposition (ALD), etc. A top electrode layer 16 is deposited on the piezoelectric layer 110. Preferably, an edge of a projection of the bottom electrode layer 13 on a horizontal plane is located outside inner edges of the protective walls 111, and a projection of the top electrode layer 16 on the horizontal plane is smaller than a projection of the bottom electrode layer 13 on the horizontal plane.

A projection area of the bottom electrode layer 13 on a horizontal plane covers projection areas of the protective walls 111 on the horizontal plane.

A projection area of the top electrode layer 16 on a horizontal plane is less than a projection area of the bottom electrode layer 13 on the horizontal plane.

The film bulk acoustic resonator 100 forms an active area, and the release channel 18 is arranged around an outer side of the active area to form a gap. The active area refers to an area where the transducer stacking structure coincides with the top electrode layer 16, the bottom electrode layer 13, and the piezoelectric layer 110.

The gap is greater than a quarter of a wavelength, and the wavelength is a ratio of an acoustic velocity of a transverse wave generated by the film bulk acoustic resonator 100 to an operating frequency.

A cross-sectional shape of the release channel in a horizontal plane is a circular section.

In conclusion, according to the film bulk acoustic resonator 100 provided in the embodiments of the disclosure, the insulating layer 11 on the substrate 10 and the transducer stacking structure on the insulating layer 11 are arranged on the substrate 10 in sequence; the substrate 10 is provided with the protective walls 111 in an etch mode to protrude out of the surface of the substrate 10, and the cavity 112 is formed between the protective walls and the transducer stacking structure and used for limiting longitudinally propagated sound waves in the transducer stacking structure; the protective walls 111 are made of a material which is non-corrodible by etching liquid or etching gas so as to ensure that the insulating layer 11 is not excessively corroded and only position and release the insulating layer area 112A of the cavity 112; and the release channel 18 in communication with the cavity 112 is formed on the transducer stacking structure, and when the cavity 112 is formed, etching liquid or etching gas is released into the insulating layer area 112A through the release channel 18 to corrode the insulating layer area 112A (cavity area), so as to obtain the cavity. The method for manufacturing the cavity 112 is simple and low in cost. The size and shape of the cavity 112 are controlled through positions of the protective walls 111, such that accurate control over cavity 112 release machining may be achieved. Moreover, the protective walls 111 have a small size, a polished area is small when a polishing process is used, a requirement for CMP is low, and a yield of products may be effectively improved. Furthermore, the transducer stacking structure is formed on the insulating layer 11, so as to advantageously reduce parasitic capacitance and resistance, and improve the comprehensive device performance.

On this basis, with reference to FIG. 9, the embodiments of the disclosure further provide a film bulk acoustic wave filter, including a positive electrode 21, a negative electrode 22 and a plurality of the film bulk acoustic resonators 100 as described in foregoing embodiments, where the positive electrode 21 is connected to a bottom electrode layer 13 or a top electrode layer 16 of one of the film bulk acoustic resonators 100, and the negative electrode 22 is connected to a top electrode layer 16 or a bottom electrode layer 13 of another one of the film bulk acoustic resonators 100.

A structure connected to an external circuit is formed after the film bulk acoustic resonator 100 is in communication with an electrode, as shown in FIG. 8, the bottom electrode layer 13 and the top electrode layer 16 in the transducer stacking structure in the film bulk acoustic resonator 100 are connected to the positive electrode 21 and the negative electrode 22 respectively. Certainly, it is possible that the bottom electrode layer 13 and the top electrode layer 16 in the transducer stacking structure in the film bulk acoustic resonator 100 are connected to the negative electrode 22 and the positive electrode 21 respectively, which is not specifically limited herein.

The film bulk acoustic resonator 100 is connected to the positive electrode 21 and the negative electrode 22 to form a level structure, and an upper side and a lower side of the level structure are each provided with ground electrodes 23.

A plurality of the film bulk acoustic resonators 100 of the foregoing embodiments are connected to each other to form a film bulk acoustic wave filter. Further, as shown in FIG. 9, the film bulk acoustic resonators 100 include a plurality of first film bulk acoustic resonators 100A and a plurality of second film bulk acoustic resonators 100B, the plurality of first film bulk acoustic resonators 100A are connected in series, and the plurality of second film bulk acoustic resonators 100B are connected to the plurality of first film bulk acoustic resonators 100A in parallel respectively.

For example, FIG. 9 shows three first film bulk acoustic resonators 100A and two second film bulk acoustic resonators 100B. After the three first film bulk acoustic resonators 100A are sequentially connected in series, the first film bulk, acoustic resonators 100A located on two sides of the series structure are connected to the positive electrode and the negative electrode respectively, and the two second film bulk acoustic resonators 100B are connected to the series structure in parallel to form the film bulk acoustic wave filter having a series-parallel structure. It is to be understood that FIG. 9 merely shows an example of interconnection of the film bulk acoustic resonators 100 and is not the only restrictive or supportable solution for interconnection of the film bulk acoustic resonators 100 of the disclosure, and that those skilled in the art will specifically set interconnection according to actual demands, which will not be repeated herein.

The film bulk acoustic wave filter includes the same structure and benefits as the film bulk acoustic resonator 100 in the foregoing embodiments. The structure and beneficial effects of the film bulk acoustic resonator 100 have been described in detail in the foregoing embodiments and will not be repeated herein.

What is described above is merely illustrative of the embodiments of the disclosure and is not intended to be limiting of the scope of protection of the disclosure, and various changes and modifications may be made by those skilled in the art. Any modifications, equivalent substitutions, improvements, and the like within the spirit and principles of the disclosure are intended to fall within the scope of protection of the disclosure.

1. A film bulk acoustic resonator, comprising a substrate, wherein two opposite protective walls protruding out of a surface of the substrate are arranged on the substrate, a cavity is formed between the two protective walls, and an insulating layer is further arranged on one side, away from the cavity, of each protective wall on the substrate; and
the film bulk acoustic resonator further comprises a transducer stacking structure, wherein the transducer stacking structure covers the insulating layer, the cavity and the protective walls, and two sides, along a stacking direction, of the transducer stacking structure are in communication with the cavity and the outside respectively.

2. The film bulk acoustic resonator according to claim 1, wherein a through release channel along the stacking direction is arranged on the transducer stacking structure, and the release channel is in communication with the cavity.

3. The film bulk acoustic resonator according to claim 1, wherein the transducer stacking structure comprises a seed layer, a bottom electrode layer, a piezoelectric film layer, a mass loading layer, a top electrode layer, and a passivation layer stacked in sequence, and the seed layer is close to the insulating layer.

4. The film bulk acoustic resonator according to claim 3, wherein the bottom electrode layer partially covers the seed layer, the mass loading layer partially covers the piezoelectric film layer, and the top electrode layer fully covers the mass loading layer and partially covers the piezoelectric film layer.

5. The film bulk acoustic resonator according to claim 4, wherein ends of the bottom electrode layer and the top electrode layer along a first direction are arranged obliquely, an inclination angle between the end of the bottom electrode layer and a horizontal plane and an inclination angle between the end of the top electrode layer and the horizontal plane are less than 30°, and the first direction is perpendicular to the stacking direction.

6. The film bulk acoustic resonator according to claim 4, wherein an angle between an end of the top electrode layer and a horizontal plane is 90°.

7. The film bulk acoustic resonator according to claim 5, wherein material of the bottom electrode layer and material of the top electrode layer both comprise any one of platinum, aluminum, tungsten or molybdenum.

8. The film bulk acoustic resonator according to claim 1, wherein an inclination angle of each of the protective walls ranges from 75° to 90°.

9. The film bulk acoustic resonator according to claim 2, wherein a cross-sectional shape, of the release channel in a horizontal plane comprises circular or elliptical or polygonal section.

10. A manufacturing method fora film bulk acoustic resonator, comprising:
etching, on a substrate, two protective walls protruding out of a surface of the substrate;
forming, on the substrate, an insulating layer, wherein a surface of the insulating layer flushes with a surface of each protective wall at a side far away from the substrate;
forming a transducer stacking structure on the insulating layer, wherein the transducer stacking structure is in communication with an insulating layer area between the two protective walls; and
corroding the insulating layer area between the two protective walls through the transducer stacking structure, so as to form a cavity after the insulating layer area between the two protective walls is corroded.

11. The manufacturing method for a film bulk acoustic resonator according to claim 10, wherein the corroding the insulating layer area between the two protective walls through the transducer stacking structure, so as to form a cavity after the insulating layer area between the two protective walls is corroded comprises:
forming a release channel, which connects the outside and the insulating layer area between the two protective walls, on the transducer stacking structure; and
releasing etching liquid or etching gas through the release channel, so as to corrode the insulating layer area between the two protective walls to form the cavity.

12. The manufacturing method for a film bulk acoustic resonator according to claim 10, wherein an inclination angle of each of the protective walls ranges from 75° to 90°.

13. The manufacturing method for a film bulk acoustic resonator according to claim 10, wherein the transducer stacking structure comprises a seed layer, a bottom electrode layer, a piezoelectric layer and a top electrode layer; and the piezoelectric layer has a plurality of layers deposited.

14. The manufacturing method for a film bulk acoustic resonator according to claim 13, wherein a projection area of the bottom electrode layer on a horizontal plane covers projection areas of the protective walls on the horizontal plane.

15. The manufacturing method fora film bulk acoustic resonator according to claim 13, wherein a projection area of the top electrode layer on a horizontal plane is less than a projection area of the bottom electrode layer on the horizontal plane.

16. The manufacturing method for a film bulk acoustic resonator according to claim 11, wherein the film bulk acoustic resonator forms an active area, and the release channel is arranged around an outer side of the active area, with a gap provided.

17. The manufacturing method for a film bulk acoustic resonator according to claim 16, wherein the gap is greater than a quarter of a wavelength, and the wavelength is a ratio of an acoustic velocity of a transverse wave to an operating frequency.

18. The manufacturing method for a film bulk acoustic resonator according to claim 16, wherein a cross-sectional shape of the release channel in a horizontal plane is a circular section.

19. A film bulk acoustic wave filter, comprising a positive electrode, a negative electrode and a plurality of interconnected film bulk acoustic resonators according to claim 1, wherein the positive electrode is connected to a bottom electrode layer or a top electrode layer of one of the film bulk acoustic resonators, and the negative electrode is connected to a top electrode layer or a bottom electrode layer of another one of the film bulk acoustic resonators.

20. The film bulk acoustic wave filter according to claim 19, wherein the film bulk acoustic resonators comprise a plurality of first film bulk acoustic resonators and a plurality of second film bulk acoustic resonators, the plurality of first film bulk acoustic resonators are connected in series, and the plurality of second film bulk acoustic resonators are connected to the plurality of first film bulk acoustic resonators in parallel respectively.
